(19) United States
(12) Patent Application Publication
(10) Pub. No.: US 2011/0073154 A1
(43) Pub. Date: Mar. 31, 2011

(54) SOLAR CELL MODULE

(75) Inventor: Toyozo NISHIDA, Takarazuka City (JP)

(73) Assignee: SANYO ELECTRIC CO., LTD., Moriguchi City (JP)

(21) Appl. No.: 12/892,270

(22) Filed: Sep. 28, 2010

(30) Foreign Application Priority Data
Sep. 29, 2009 (JP) 2009-224664

(51) Int. Cl. H01L 31/05

(52) U.S. Cl. 136/244

(57) ABSTRACT

A solar cell module that includes a plurality of solar cells each of which has a photoelectric conversion body configured to generate carriers upon exposure to light; and an electrode provided on the main surface of the photoelectric conversion body, and configured to collect the carriers from the photoelectric conversion body; a wiring member configured to electrically connect the plurality of solar cells; and a wiring substrate that covers main surfaces of at least two or more solar cells out of the plurality of solar cells, the wiring substrate comprising a groove provided along at least a part of the electrodes, wherein a conductive member is provided at a bottom of the groove, and the conductive member electrically connects the electrodes to the wiring member.

### CROSS REFERENCE TO RELATED APPLICATIONS

This application is based upon and claims the benefit of priority from Japanese Patent Application No. P2009-224664 entitled “SOLAR CELL MODULE,” filed on Sep. 29, 2009, the entire content of which are incorporated by reference.

### BACKGROUND OF THE INVENTION

1. Field of the Invention

The invention relates to a solar cell module in which multiple solar cells are electrically connected to each other by a wiring member.

2. Description of the Related Art

Solar cells are expected to be a new energy source because they directly convert clean and inexhaustibly supplied sunlight into electricity. In order to increase output, a solar cell module consists of multiple solar cells connected together. In a solar cell module, multiple solar cells are electrically connected to each other by a wiring member.

A solar cell includes, for example, a photoelectric conversion body that generates carriers upon exposure to light (e.g., sunlight), and an electrode that collects the carriers from the photoelectric conversion body. Specifically, the photoelectric conversion body has a light-receiving surface that receives irradiated light, and a rear surface provided on the opposite side to the light-receiving surface. The electrode is provided on the light-receiving surface and the rear surface of the photoelectric conversion body. The light-receiving surface and the rear surface are collectively called the main surface of the photoelectric conversion body.

Here, in order to simplify the manufacturing process of a solar cell module, a technology has been proposed that uses a wiring substrate in which a pattern of electrodes is formed (for example, Patent Document 1: Japanese Patent Application Publication No. 2002-319691, Patent Document 2: Japanese Patent Application Publication No. 2005-340362, and Patent Document 3: Japanese Patent Application Publication No. 2007-019334).

### SUMMARY OF THE INVENTION

An aspect of the invention provides a solar cell module that comprises: a plurality of solar cells each comprising: a photoelectric conversion body configured to generate carriers upon exposure to light; and an electrode provided on the main surface of the photoelectric conversion body, and configured to collect the carriers from the photoelectric conversion body; a wiring member configured to electrically connect the plurality of solar cells; and a wiring substrate that covers main surfaces of at least two or more solar cells out of the plurality of solar cells, the wiring substrate comprising a groove provided along at least a part of the electrodes, wherein a conductive member is provided at a bottom of the groove, and the conductive member electrically connects the electrodes to the wiring member.

### BRIEF DESCRIPTION OF THE DRAWINGS

FIG. 1 is a view showing a configuration of solar cell module 100 according to a first embodiment;

FIG. 2 is a view showing a configuration of solar cell module 100 according to the first embodiment;

FIG. 3 is a view showing a configuration of solar cell 10 according to the first embodiment;

FIG. 4 is a view showing the configuration of solar cell 10 according to the first embodiment;

FIG. 5 is a view showing the configuration of solar cell 10 according to the first embodiment;

FIG. 6 is a view showing the configuration of solar cell 10 according to the first embodiment;

FIG. 7 is a view showing an arrangement of solar cells 10 according to the first embodiment;

FIG. 8 is a view showing a configuration (1) of wiring substrate 30 according to the first embodiment;

FIG. 9 is a view showing the configuration (1) of wiring substrate 30 according to the first embodiment;

FIG. 10 is a view showing connection between solar cells 10 according to the first embodiment;

FIG. 11 is a view showing the connection between solar cells 10 according to the first embodiment;

FIG. 12 is a view showing the connection between solar cells 10 according to the first embodiment;

FIG. 13 is a view showing a configuration (2) of wiring substrate 30 according to the first embodiment;

FIG. 14 is a view showing the configuration (2) of wiring substrate 30 according to the first embodiment;

FIG. 15 is a view showing a configuration of wiring substrate 30 according to modification example 1 of the first embodiment;

FIG. 16 is a view showing an arrangement of solar cells 10 according to modification example 2 of the first embodiment;

FIG. 17 is a view showing a configuration of wiring substrate 30 according to modification example 2 of the first embodiment;

FIG. 18 is a view showing connection between solar cells 10 according to modification example 2 of the first embodiment;

FIG. 19 is a view showing an arrangement of solar cells 10 according to a second embodiment;

FIG. 20 is a view showing a configuration of wiring substrate 30 according to the second embodiment;

FIG. 21 is a view showing connection between solar cells 10 according to the second embodiment;

FIG. 22 is a view showing an arrangement of solar cells 10 according to modification example 1 of the second embodiment;

FIG. 23 is a view showing a configuration of wiring substrate 30 according to modification example 1 of the second embodiment;

FIG. 24 is a view showing connection between solar cells 10 according to modification example 1 of the second embodiment;

FIG. 25 is a view showing the connection between solar cells 10 according to modification example 1 of the second embodiment;

FIG. 26 is a view showing a configuration of solar cell module 100 according to a third embodiment;

FIG. 27 is a view showing a configuration of solar cell 10 according to the third embodiment;

FIG. 28 is a view showing the configuration of solar cell 10 according to the third embodiment; and

FIG. 29 is a view showing connect ion between solar cells 10 according to the third embodiment.

### DETAILED DESCRIPTION OF EMBODIMENTS

In the following, solar cell modules according to embodiments are described with reference to the drawings. In the following description of the drawings, identical or similar reference numerals are assigned to identical or similar components.

All of the drawings are provided for the purpose of illustrating the respective examples only. No dimensional proportion in the drawings shall impose a restriction on the drawings. For this reason, specific dimensions and the like should be interpreted by with the following descriptions taken into consideration. In addition, the drawings include parts whose dimensional relationship and ratio are different from one drawing to another.

Prepositions, such as “on”, “over” and “above” may be defined with respect to a surface, for example a layer surface, regardless of that surface's orientation in space. The preposition “above” may be used in the specification and claims even if a layer is in contact with another layer. The preposition “on” may be used in the specification and claims when a layer is not in contact with another layer, for example, when there is an intervening layer between them.

In the solar cell module according to each embodiment, multiple solar cells are electrically connected to each other by a wiring member. The solar cell module includes a wiring substrate that covers the main surfaces of at least two or more solar cells of the multiple solar cells. Each of the multiple solar cells includes a photoelectric conversion body that generates carriers upon exposure to light, and an electrode that is provided on the main surface of the photoelectric conversion body, and collects the carriers from the photoelectric conversion body. The wiring substrate has a groove provided along at least a part of the electrode. A conductive member is provided at the bottom of the groove. The conductive member provided at the bottom of the groove connects the electrode to the wiring member.

In the embodiments, the wiring substrate has a groove provided along at least a part of the electrode. Thus, alignment of the wiring substrate with at least two solar cells is easy.

In the embodiments, a conductive member is provided at the bottom of the groove provided in the wiring substrate, the conductive member connecting the electrode to the wiring member. Consequently, wiring such as tab wiring can be simplified. That is, the manufacturing process of the solar cell module is simplified.

### First Embodiment

### Configuration of Solar Cell Module

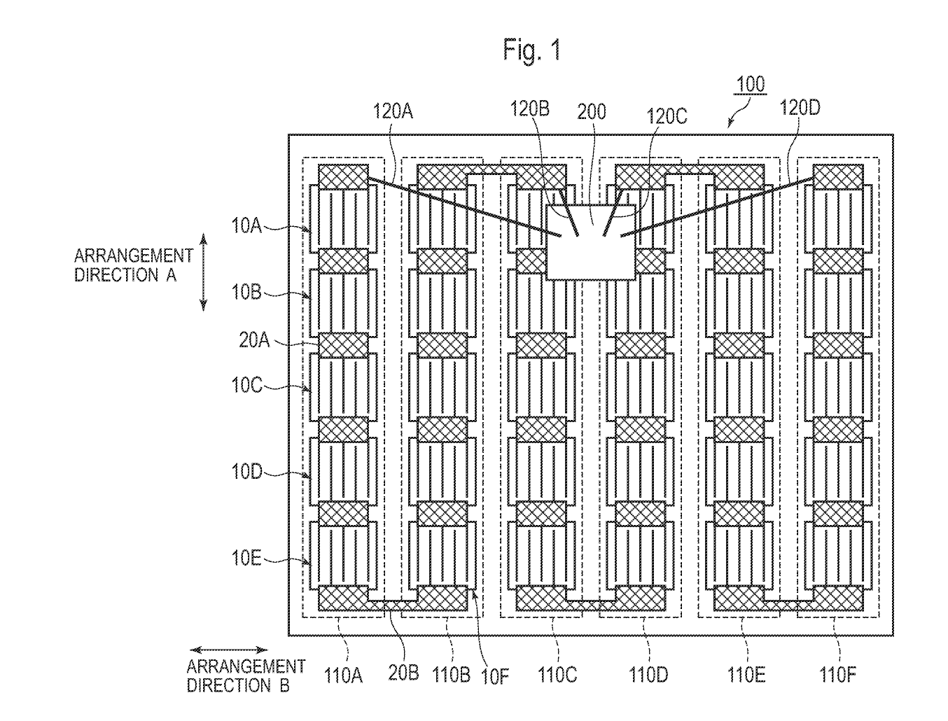

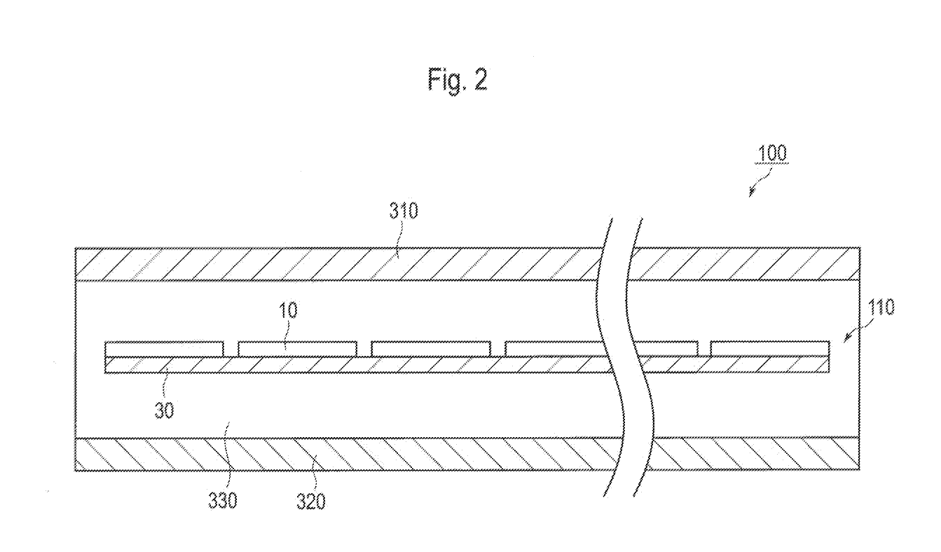

In the following, the configuration of a solar cell module according to the first embodiment is described with reference to the drawings. FIGS. 1 and 2 are views showing the configuration of solar cell module 100 according to the first embodiment. Note that FIG. 1 is a view of solar cell module 100 viewed from the rear surface that is provided on the opposite side to the light-receiving surface which receives irradiated light. FIG. 2 is a view showing a cross section of solar cell module 100. Note that FIG. 1 is shown with rear surface member 320 omitted.

Solar cell module 100 includes multiple solar cell linear arrays 110 (solar cell array 110A to solar cell array 110F), and terminal box 200 as shown in FIG. 1.

The multiple solar cell arrays 110 are arranged in arrangement direction B, and each solar cell array 110 has multiple solar cells 10. In solar cell array 110, multiple solar cells 10 are arranged in arrangement direction A.

Here, in solar cell array 110, multiple solar cells 10 are electrically connected to each other by wiring member 20A. Between solar cell arrays 110, multiple solar cells 10 are electrically connected to each other by wiring member 20B. In the following, wiring member 20A and wiring member 20B are collectively called wiring member 20.

For example, solar cell array 110A has solar cells 10A to 10E. Solar cells 10A to 10E are electrically connected to each other by wiring member 20A.

Solar cell 10E provided at one end of solar cell array 110A and solar cell 10F provided at one end of solar cell array 110B are electrically connected to each other by wiring member 20B.

Terminal box 200 is disposed on the rear surface provided on the opposite side to the light-receiving surface that receives irradiated light. Terminal box 200 is connected with multiple lead electrodes 120 (lead electrodes 120A to 120D) that are connected to wiring member 20. Terminal box 200 outputs electric power via wiring member 20 and lead electrodes 120 to the outside via an output cable (not shown). Lead electrodes 120A to 120D are connected to wiring member 20B that electrically connects multiple solar cells 10 to each other between solar cell arrays 110.

Solar cell module 100 has light-receiving surface member 310, rear surface member 320, and sealing material 330 as shown in FIG. 2. Solar cell array 110 is sealed with sealing material 330 between light-receiving surface member 310 and rear surface member 320.

Light-receiving surface member 310 is provided on the light-receiving surface side of solar cell 10, and protects the light-receiving surface of solar cell 10. Light-receiving surface member 310 is made of glass or plastic that is transparent and impervious to water.

Rear surface member 320 is provided on the rear surface side of solar cell 10, and protects the rear surface of solar cell 10. Rear surface member 320 is, for example, a resin film such as PET (Polyethylene Terephthalate) or a laminated film having a structure in which an Al foil is sandwiched between resin films.

Sealing material 330 is filled between light-receiving surface member 310 and rear surface member 320. Sealing material 330 includes a transparent member. Sealing material 330 is made of, for example, a resin such as EVA, EEA, PVB, silicone, urethane, acrylic, or epoxy.

Wiring substrate 30 is provided on the rear surface side of multiple solar cells 10. Wiring substrate 30 includes an insulating member, and covers the rear surfaces of at least two or more solar cells 10.

### (Configuration of Solar Cell)

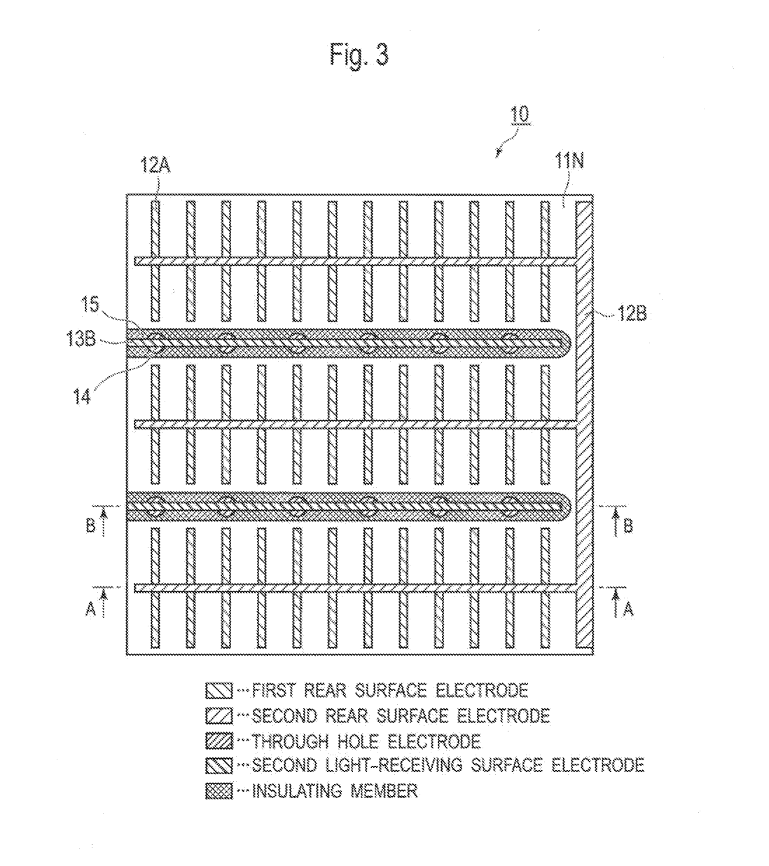

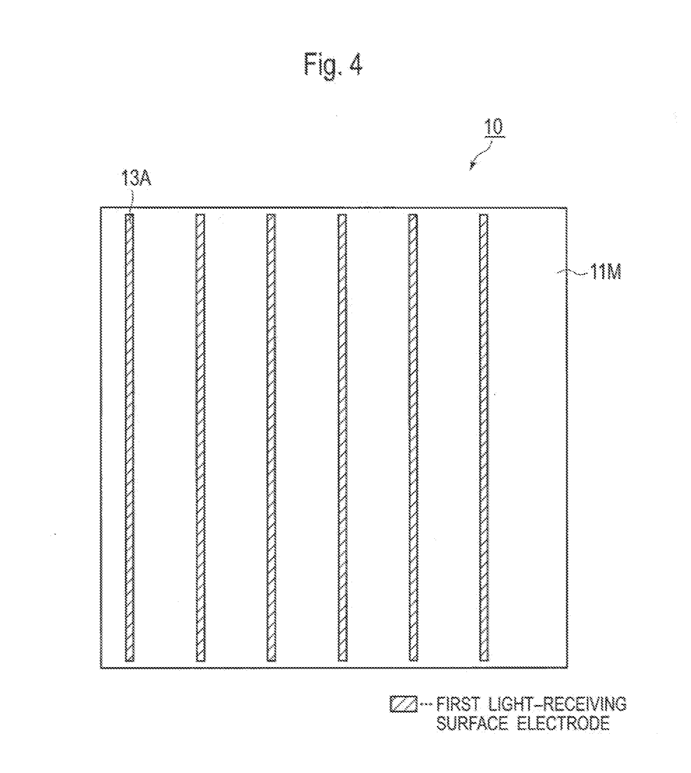

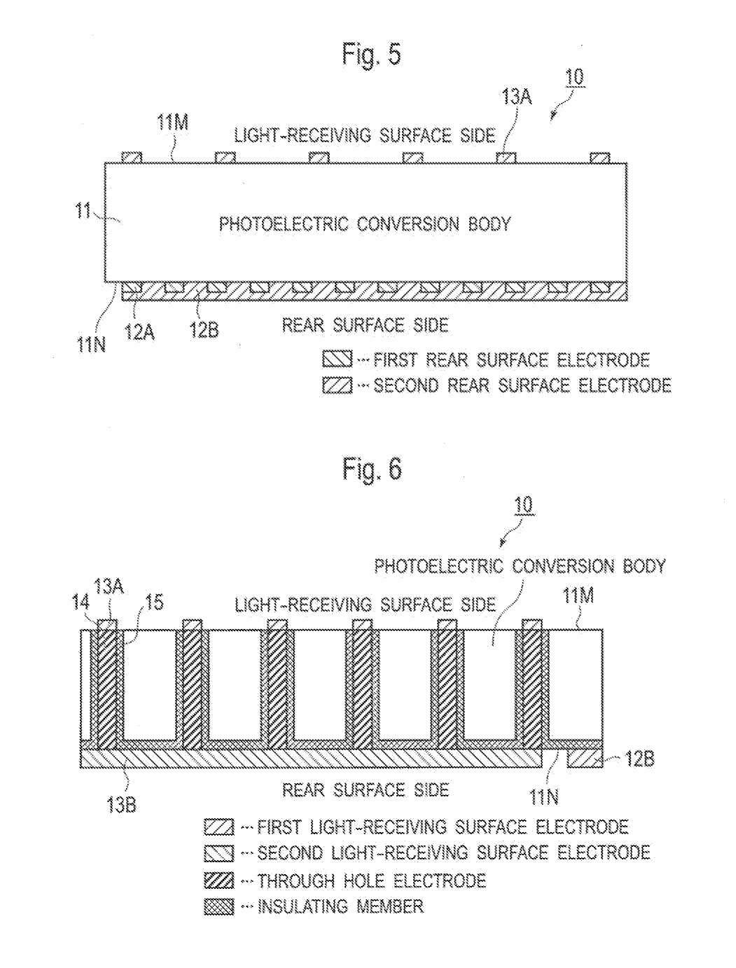

In the following, the configuration of the solar cell according to the first embodiment is described with reference to the drawings. FIGS. 3 to 6 are views showing the configuration of solar cell 10 according to the first embodiment. Note that FIG. 3 is a view of solar cell 10 viewed from the rear surface that is provided on the opposite side to the light-receiving surface which receives irradiated light. FIG. 4 is a view of solar cell 10 viewed from the light-receiving surface that receives irradiated light. FIG. 5 is a view showing a cross section of solar cell 10 (the cross-section taken along the line A-A shown in FIG. 3). FIG. 6 is a view showing a cross section of solar cell 10 (the cross-section taken along the line B-B shown in FIG. 3).

As shown in FIGS. 3 to 6, solar cell 10 has photoelectric conversion body 11, first electrode 12, second electrode 13, through hole electrode 14, and insulating member 15.

Photoelectric conversion body 11 generates carriers upon exposure to light. The carriers are a pair of a positive hole and a negative electron. Photoelectric conversion body 11 has light-receiving surface 11M that receives irradiated light, and rear surface 11N provided on the opposite side to light-receiving surface 11M. In the first embodiment, a first conductivity type region is formed in light-receiving surface 11M of photoelectric conversion body 11, and a second conductivity type region is formed in rear surface 11N of photoelectric conversion body 11.

Photoelectric conversion body 11 may include a semiconductor substrate made of crystalline semiconductor material such as monocrystal Si and polycrystal Si. Photoelectric conversion body 11 may include a semiconductor substrate made of compound semiconductor material such as GaAs or InP.

Photoelectric conversion body 11 may include a structure having intrinsic amorphous Si between a monocrystal Si substrate and an amorphous Si layer (HIT structure). The HIT structure improves the characteristic of a heterojunction interface.

First electrode 12 is an electrode that collects carriers (positive holes or electrons). Specifically, first electrode 12 has first rear surface electrode 12A and second rear surface electrode 12B.

First rear surface electrode 12A has a linear shape extending in arrangement direction B, and is provided on rear surface 11N of photoelectric conversion body 11. Multiple first rear surface electrodes 12A are preferably disposed substantially across the entire area of rear surface 11N of photoelectric conversion body 11.

Second rear surface electrode 12B has a linear shape portion extending in arrangement direction A and a linear shape portion extending in arrangement direction B, and is provided on rear surface 11N of photoelectric conversion body 11. The linear shape portion extending in arrangement direction B is provided at end portion in arrangement direction A of solar cell 10.

Here, second rear surface electrode 12B intersects with and is electrically connected to multiple first rear surface electrodes 12A on rear surface 11N of photoelectric conversion body 11.

First rear surface electrode 12A and second rear surface electrode 12B comprises, for example, low resistance metal such as Ag and Cu.

Second electrode 13 is an electrode that collects carriers (positive holes or electrons). Specifically, second electrode 13 has first light-receiving surface electrode 13A and second light-receiving surface electrode 13B.

First light-receiving surface electrode 13A has a linear shape extending in arrangement direction B, and is provided on light-receiving surface 11M of photoelectric conversion body 11. Multiple first light-receiving surface electrodes 13A are preferably disposed substantially across the entire area of light-receiving surface 11M of photoelectric conversion body 11.

Second light-receiving surface electrode 13B has a linear shape extending in arrangement direction A, and is provided on rear surface 11N of photoelectric conversion body 11. Here, second light-receiving surface electrode 13B intersects with multiple first light-receiving surface electrodes 13A on a projection plane approximately parallel to the main surface of photoelectric conversion body 11 (light-receiving surface 11M or rear surface 11N)

First light-receiving surface electrode 13A and second light-receiving surface electrode 13B are made of, for example, low resistance metal such as Ag and Cu.

Second light-receiving surface electrode 13B is not directly connected to second rear surface electrode 12B.

Through hole electrode 14 is provided in a through hole that passes through photoelectric conversion body 11. Through hole electrode 14 electrically connects first light-receiving surface electrode 13A to second light-receiving surface electrode 13B. Through hole electrode 14 is made of, for example, low resistance metal such as Ag and Cu.

Although through hole electrode 14 protrudes from second light-receiving surface electrode 13B in FIG. 3, through hole electrode 14 may be configured not to protrude from second light-receiving surface electrode 13B. That is, through hole electrode 14 may be covered with second light-receiving surface electrode 13B.

Insulating member 15 is provided in a through hole that passes through photoelectric conversion body 11. Insulating member 15 covers the outer circumference of through hole electrode 14. Insulating member 15 insulates through hole electrode 14 from photoelectric conversion body 11. Insulating member 15 may insulate through hole electrode 14 from first rear surface electrode 12A.

### (Arrangement of Solar Cells)

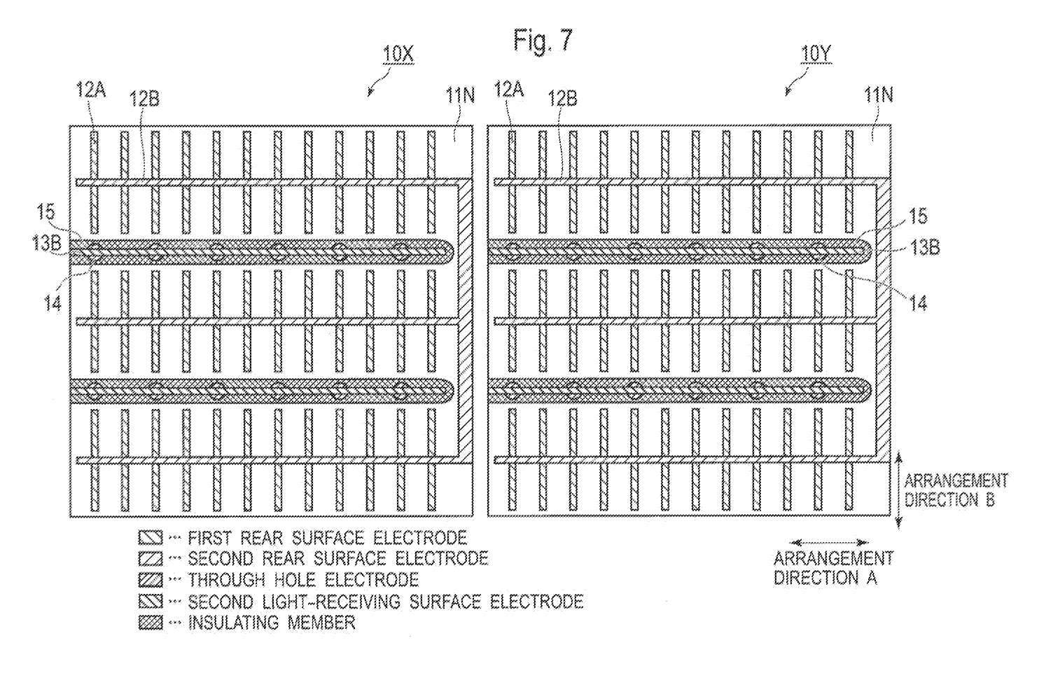

In the following, the arrangement of the solar cells according to the first embodiment is described with reference to the drawings. FIG. 7 is a view showing an arrangement of solar cells 10 according to the first embodiment. Note that FIG. 7 is a view of solar cells 10 viewed from the rear surface side.

Here, solar cell 10X and solar cell 10Y out of multiple solar cells 10 are described as an example. Solar cell 10X and solar cell 10Y are solar cells 10 adjacent to each other in solar cell array 110. For example, solar cell 10X is solar cell 10A provided in solar cell array 110A, and solar cell 10Y is solar cell 10B provided in solar cell array 110A (see FIG. 1).

In the first embodiment, solar cell 10X and solar cell 10Y have the same configuration as shown in FIG. 7. Also, the directions of solar cell 10X and solar cell 10Y are the same.

### (Configuration (1) of Wiring Substrate)

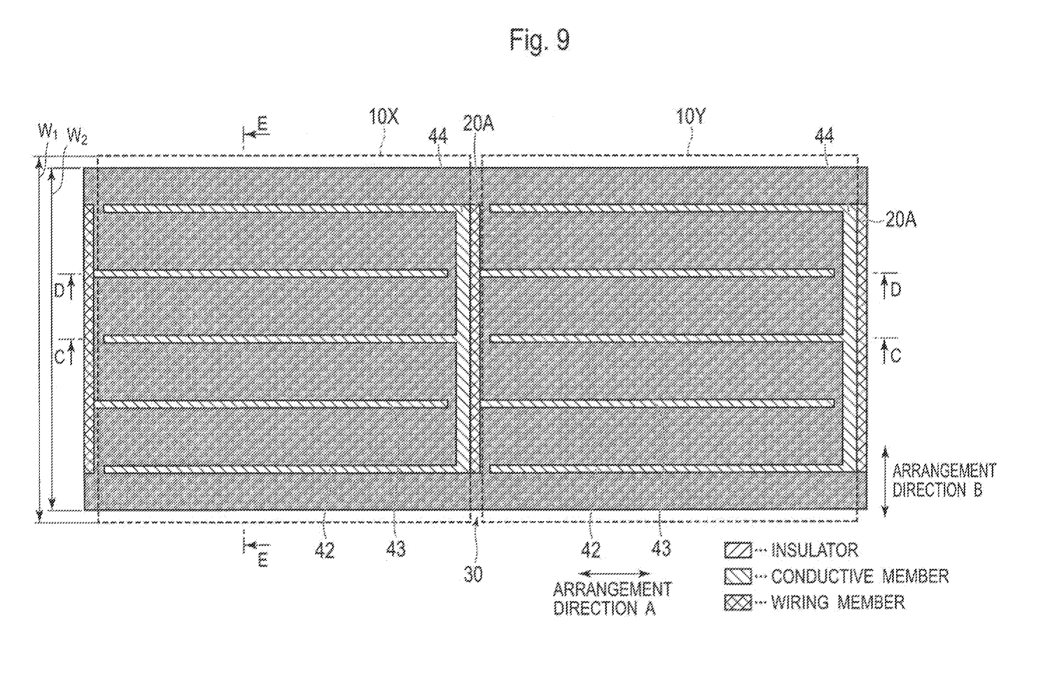

In the following, the configuration (1) of the wiring substrate according to the first embodiment is described with reference to the drawings. FIGS. 5 and 9 are views showing wiring substrate 30 according to the first embodiment.

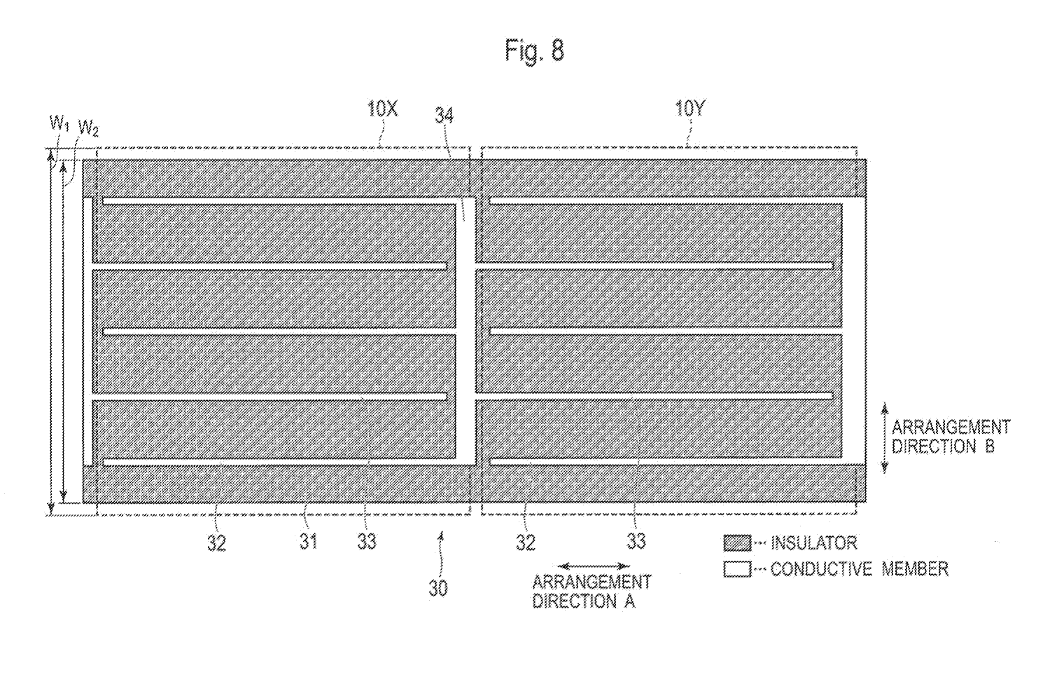

Here, the case is illustrated where wiring substrate 30 covers rear surface 11N of solar cell 10X and rear surface 11N of solar cell 10Y. FIGS. 8 and 9 are views showing one of the faces of wiring substrate 30, which is opposed to rear surface 11N.

As shown in FIG. 8, wiring substrate 30 includes insulator 31, and insulator 31 has groove 32, groove 33, and groove 34. For insulator 31, a rubber resin, a silicone resin, a urethane resin, an epoxy resin, a resin having a porous structure, and the like may be used.

Groove 32 is provided along a part of first electrode 12, i.e., second rear surface electrode 12B. Groove 33 is provided along a part of second electrode 13, i.e., second light-receiving surface electrode 13B. Groove 34 is provided along a part of second rear surface electrode 12B. Also, groove 32 on solar cell 10X side communicates with groove 34, and groove 33 on solar cell 10Y side communicates with groove 34.

As shown in FIG. 9, conductive member 42 is provided at the bottom of groove 32, and conductive member 43 is provided at the bottom of groove 33. Also, conductive member 44 and wiring member 20A are provided at the bottom of groove 34. Conductive member 42, conductive member 43, and conductive member 44 are made of a conductive material similar to wiring member 20A.

Note that, in the first embodiment, it is just stated that conductive member 44 and wiring member 20A are provided at the bottom of groove 34 for convenience of the description. However, as is apparent from the condition that conductive member 44 and wiring member 20A are made of a similar conductive material, conductive member 44 and wiring member 20A provided at the bottom of groove 34 does not necessarily have to be distinguished.

Since groove 32 on solar cell 10X side communicates with groove 34 as described above, conductive member 42 on solar cell 10X side is connected to wiring member 20A via conductive member 44. Similarly, since groove 33 on solar cell 10Y side communicates with groove 34, conductive member 43 on solar cell 10Y side is connected to wiring member 20A.

Here, when wiring substrate 30 is provided on rear surface 11N of solar cell 10X and rear surface 11N of solar cell 10Y, conductive member 42 is electrically connected to second rear surface electrode 12B, and conductive member 43 is electrically connected to second light-receiving surface electrode 13B.

In other words, second rear surface electrode 12B of solar cell 10X is electrically connected to wiring member 20A via conductive member 42 and conductive member 44. Similarly, second light-receiving surface electrode 13B of solar cell 10Y is electrically connected to wiring member 20A via conductive member 43.

That is, solar cell 10X and solar cell 10Y are electrically connected to each other by wiring member 20A.

In the first embodiment, width W₂ of wiring substrate 30 in arrangement direction B is smaller than width W₁ of solar cell 10X for solar cell 10Y). In other words, width W₂ of wiring substrate 30 is smaller than width W₁ of solar cell array 110.

The depth of the grooves (groove 32, groove 33, and groove 34), the thickness of the conductive members (conductive member 42, conductive member 43, and conductive member 44), and the relationship between the electrodes (first electrode 12 and second electrode 13) are preferably as shown below.

The depth of the groove is preferably in a range of 10 μm to 1000 μm. The thickness of the conductive member is preferably 1 μm to “the depth of the groove −1” μm. The thickness of the electrode is preferably several 10 μm.

Furthermore, when the thickness of the wiring substrate (wiring substrate 30) is 100 μm, the depth of the groove is preferably 60 μm, the thickness of the conductive member is preferably 20 μm or more, and the thickness of the electrode is preferably 40 μm or more.

In order to have a better contact between the conductive member and the electrode, the depth of the groove is preferably approximately 10 μm less than “the thickness of the conductive member”+“the thickness of the electrode.”

### (Connection Between Solar Cells)

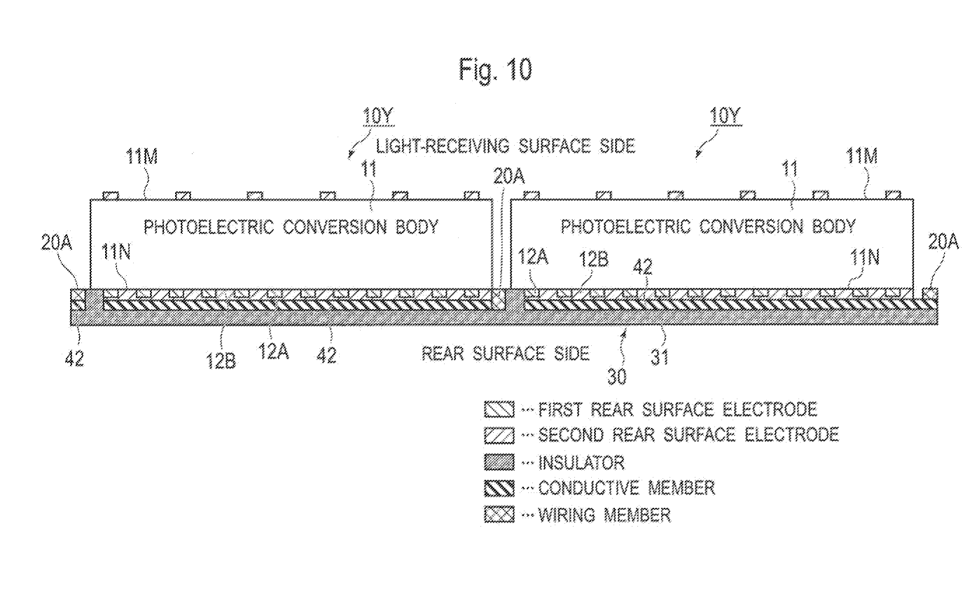

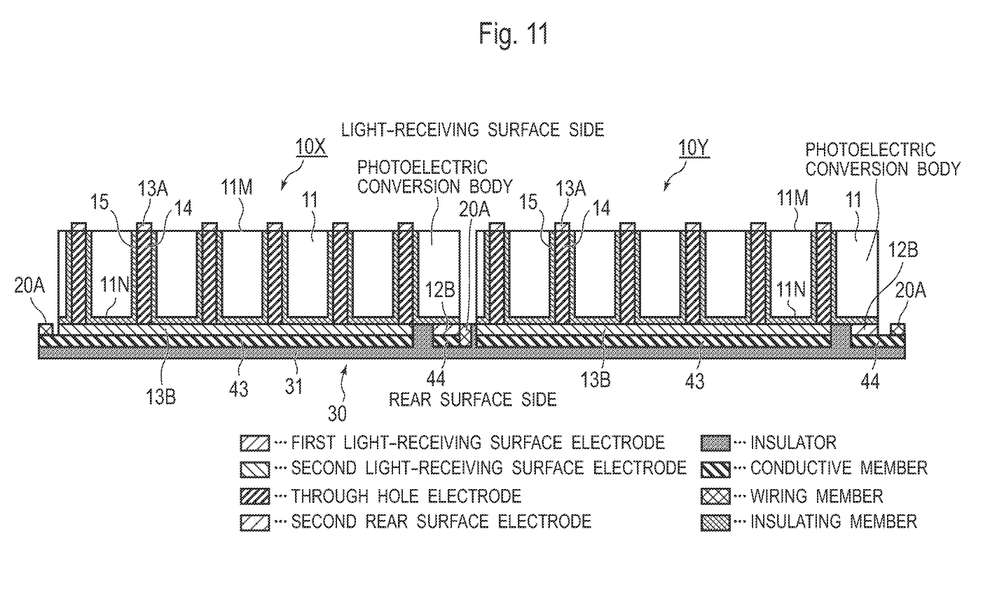

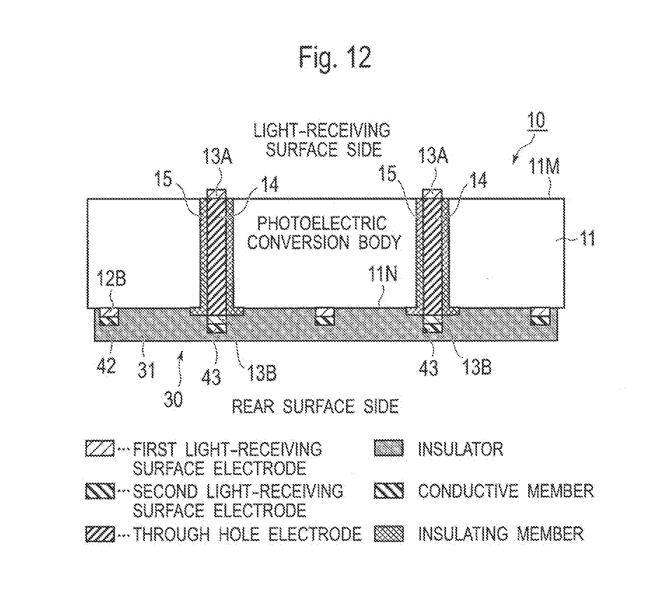

In the following, the connection between the solar cells according to the first embodiment is described with reference to the drawings. FIGS. 10 to 12 are views showing the cross sections of solar cell 10 and wiring substrate 30 according to the first embodiment. Specifically, FIG. 10 is a view showing the cross sections (taken along the line C-C shown in FIG. 9) of solar cell 10 and wiring substrate 30. FIG. 11 is a view showing the cross sections (taken along the line D-D shown in FIG. 9) of solar cell 10 and wiring substrate 30. FIG. 12 is a view showing the cross sections (taken along the line E-E shown in FIG. 9) of solar cell 10 and wiring substrate 30.

As shown in FIG. 10, second rear surface electrode 12B of solar cell 10X is electrically connected to wiring member 20A via conductive member 42. On the other hand, second rear surface electrode 12B of solar cell 10X is insulated from second rear surface electrode 12B of solar cell 10Y by wiring substrate 30 (insulator 31).

As shown in FIG. 11, second light-receiving surface electrode 13B of solar cell 10Y is electrically connected to wiring member 20A via conductive member 43. On the other hand, second light-receiving surface electrode 13B of solar cell 10Y is insulated from second light-receiving surface electrode 13B of solar cell 10X by wiring substrate 30 (insulator 31).

As shown in FIG. 12, in solar cell 10X, second rear surface electrode 12B is insulated from second light-receiving surface electrode 13B by wiring substrate 30 (insulator 31).

As shown in FIGS. 10 to 12, second rear surface electrode 12B and second light-receiving surface electrode 13B are provided so as not to be electrically connected to each other in solar cell 10X (or solar cell 10Y). On the other hand, second rear surface electrode 12B of solar cell 10X and second light-receiving surface electrode 13B of solar cell 10Y are electrically connected to each other by wiring member 20A.

### (Configuration (2) of Wiring Substrate)

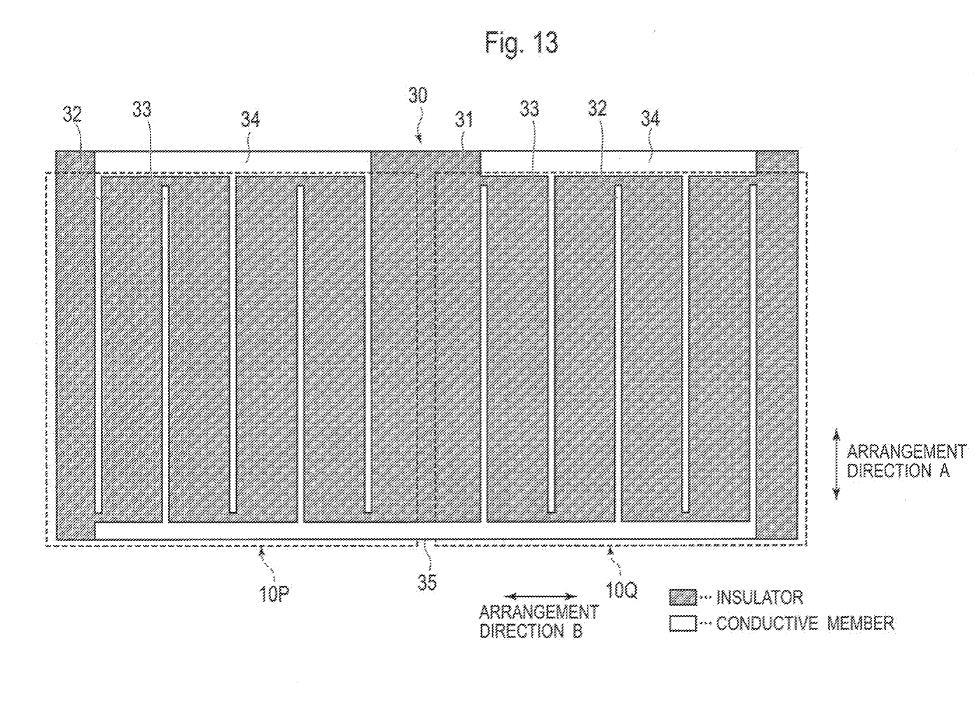

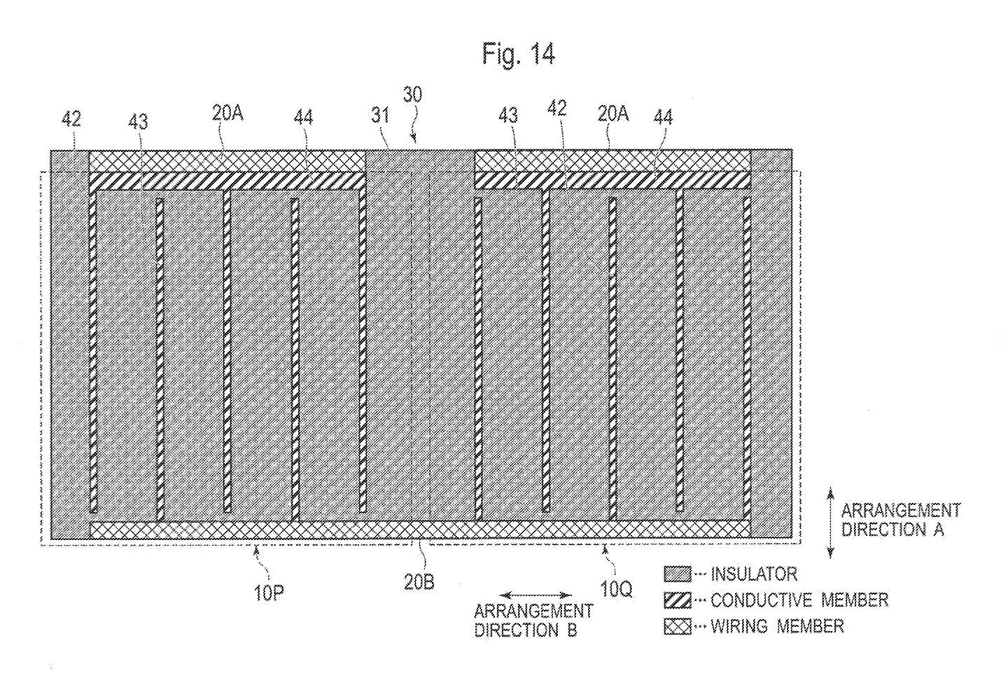

In the following, the configuration (2) of the wiring substrate according to the first embodiment is described with reference to the drawings. FIGS. 13 and 14 are views showing wiring substrate 30 according to the first embodiment.

Here, solar cell 10P and solar cell 10Q out of multiple solar cells 10 are described as an example. Solar cell 10P and solar cell 10Q are solar cells 10 adjacent to each other between two adjacent solar cell arrays 110. For example, solar cell 10P is solar cell 10E provided at one end of solar cell array 110A, and solar cell 10Q is solar cell 10F provided at one end of solar cell array 110B (see FIG. 1).

Also, the case is illustrated where wiring substrate 30 covers rear surface 11N of solar cell 10P and rear surface 11N of solar cell 10Q. FIGS. 13 and 14 are views showing one of the faces of wiring substrate 30, which is opposed to rear surface 11N.

As shown in FIG. 13, wiring substrate 30 includes insulator 31, and insulator 31 has groove 35 in addition to groove 32, groove 33, and groove 34. Groove 32, groove 33, and groove 34 are similar to groove 32, groove 33, and groove 34 shown in FIG. 8.

Groove 35 extends continuously across solar cell 10P and solar cell 10Q. Specifically, groove 35 extends continuously across one end of solar cell 10P and one end of solar cell 10Q in arrangement direction A. Also, groove 35 communicates with groove 33 on solar cell lop side and groove 32 on solar cell 10Q side.

As shown in FIG. 14, conductive member 42 is provided at the bottom of groove 32, and conductive member 43 is provided at the bottom of groove 33. Conductive member 44 and wiring member 20A are provided at the bottom of groove 34.

Here, wiring member 203 is provided at the bottom of groove 35, the wiring member 20B electrically connecting multiple solar cells 10 to each other between two adjacent solar cell arrays 110. Since groove 33 on solar cell 10P side communicates with groove 35 as described above, conductive member 43 on solar cell 10P side is connected to wiring member 20B. Similarly, since groove 32 of solar cell 10Q communicates with groove 35, conductive member 42 on solar cell 10Q side is connected to wiring member 20B.

In other words, second light-receiving surface electrode 13B of solar cell 10P is electrically connected to wiring member 20B via conductive member 43. Similarly, second rear surface electrode 12B of solar cell 10Q is electrically connected to wiring member 20B via conductive member 42.

That is, solar cell 10P and solar cell 10Q are electrically connected to each other by wiring member 20B.

### (Operations and Effects)

In this embodiment, groove 32 and groove 33 in wiring substrate 30 are provided along second rear surface electrode 12B and second light-receiving surface electrode 13B. Consequently, alignment of wiring substrate 30 with at least two or more solar cells 10 is easy.

In this embodiment, the conductive members (conductive member 42 and conductive member 43) are provided at the bottom of the grooves (groove 32 and groove 33) provided in wiring substrate 30, and the conductive member (conductive member 42 or conductive member 43) connects the electrode (second rear surface electrode 12B or second light-receiving surface electrode 13B) to wiring member 20. Consequently, wiring of wiring member such as tab wiring can be simplified. That is, the manufacturing process of solar cell module 100 is simplified.

Specifically, the two cases shown below are conceivable. Case (1) is where solar cells 10 adjacent to each other (solar cell 10X and solar cell 10Y) are electrically connected to each other in solar cell array 110. Case (2) is where solar cells 10 adjacent to each other (solar cell 10P and solar cell 10Q) are electrically connected to each other between two adjacent solar cell strings 110.

In case (1), second rear surface electrode 12B of solar cell 10X is electrically connected to wiring member 20A via conductive member 42 and conductive member 44. Similarly, second light-receiving surface electrode 13B of solar cell 10Y is electrically connected to wiring member 20A via conductive member 43. Thereby, solar cell 10X and solar cell 10Y are electrically connected to each other by wiring member 20A.

In case (1), wiring member 20A is provided in groove 34 that is provided in wiring substrate 30. Consequently, wiring of the wiring member, which is used for electrically connecting multiple solar cells 10 to each other in solar cell array 110, can be omitted, thus the manufacturing process of solar cell module 100 is simplified.

In case (2), second light-receiving surface electrode 13B of solar cell 10P is electrically connected to wiring member 20B via conductive member 43. Similarly, second rear surface electrode 12B of solar cell 10Q is electrically connected to wiring member 20B via conductive member 42. Thereby, solar cell 10P and solar cell 10Q are electrically connected to each other by wiring member 208.

In case (2), wiring member 2013 is provided in groove 35 that is provided in wiring substrate 30. Consequently, wiring of the wiring member, which is used for electrically connecting multiple solar cells 10 to each other between two adjacent solar cell arrays 110, can be omitted, thus the manufacturing process of solar cell module 100 is simplified.

In the above-described case (1) in this embodiment, width W₂ of wiring substrate 30 is smaller than width W₁ of solar cell string 110. Thus, the space between solar cell arrays 110 can be reduced. That is, the scale of integration of solar cells 10 can be increased.

In the above-described case (2) in this embodiment, lead electrode 120 is provided to wiring member 20B (see FIG. 1). Thus, lead electrode 120 does not protrude to the outside of solar cell string 110 in arrangement direction 8, which allows suppressing an increase of the size of solar cell module 100.

### Modification Example 1

In the following, modification example 1 of the first embodiment is described with reference to the drawings. In the following, points of modification example 1 different from those of the first embodiment are mainly described.

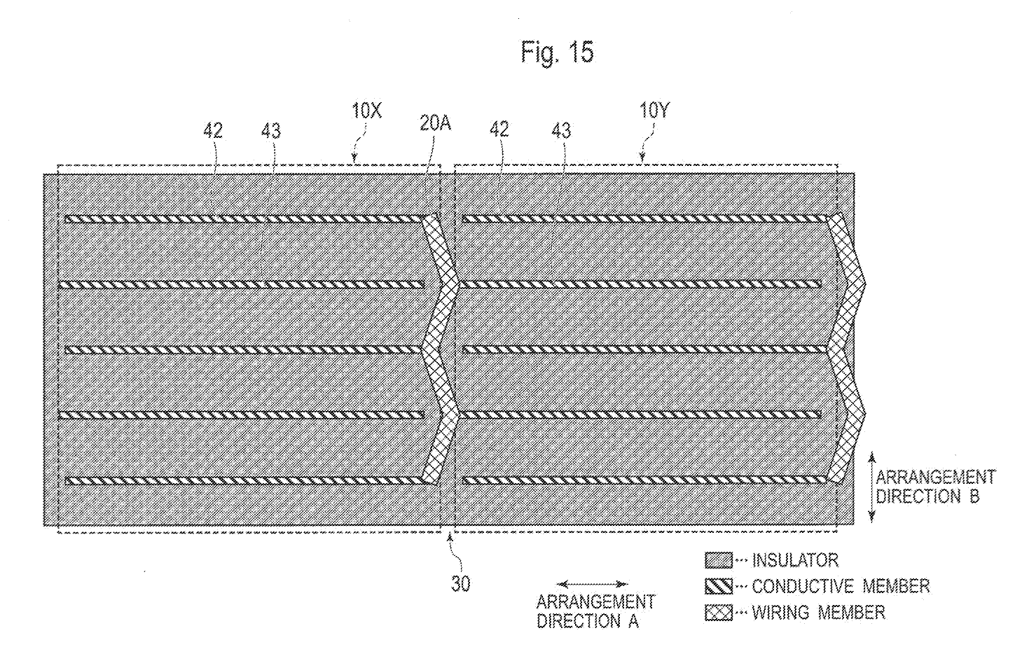

Specifically, in the first embodiment, wiring member 20A has a linear shape. On the other hand, in modification example 1, wiring member 20A has a zigzag shape as shown in FIG. 15.

modification example 1 is similar to the first embodiment in that wiring member 20A is provided in groove 34 of wiring substrate 30. That is, groove 34 of wiring substrate 30 has a zigzag shape.

### Modification Example 2

In the following, modification example 2 of the first embodiment is described with reference to the drawings. In the following, points of modification example 2 different from those of the first embodiment are mainly described.

Specifically, in modification example 2, the pattern of the electrodes is different from that of the first embodiment. Also, in modification example 2, an elastic member is provided between the bottom of the grooves (groove 32 and groove 33) and the conductive members (conductive member 42 and conductive member 43).

### (Arrangement of Solar Cells)

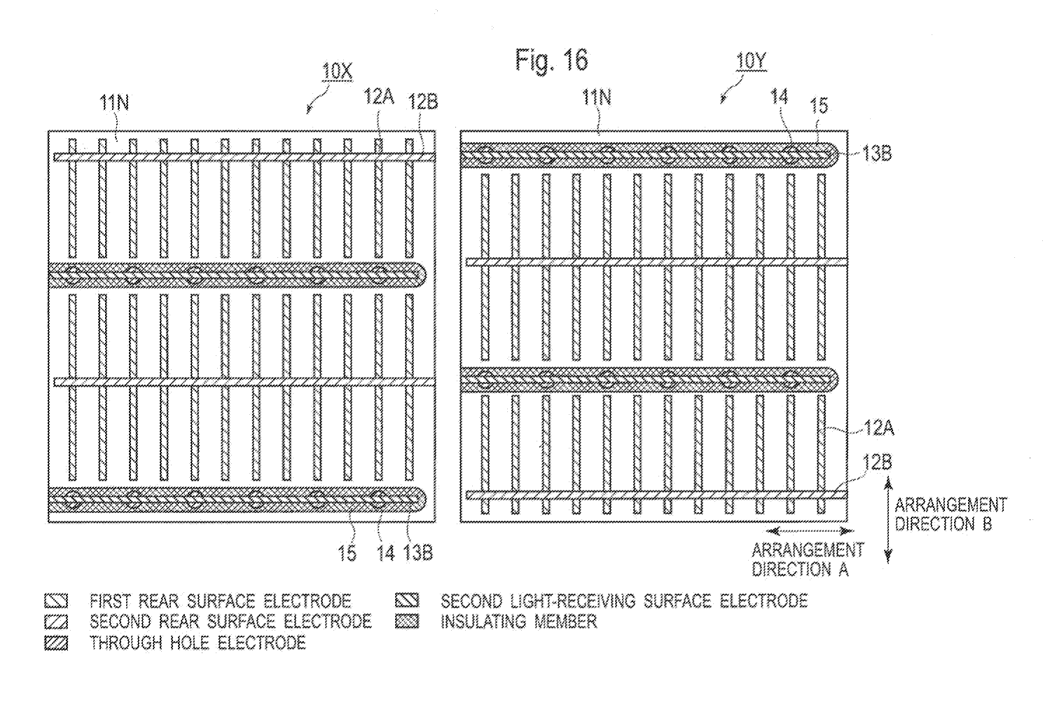

In the following, an arrangement of solar cells according to modification example 2 is described with reference to the drawings. FIG. 16 is a view showing an arrangement of solar cells 10 according to modification example 2. Note that FIG. 16 is a view of solar cells 10 viewed from the rear surface side.

Here, solar cell 10X and solar cell 10Y out of multiple solar cells 10 are described as an example. Solar cell 10X and solar cell 101 are solar cells 10 adjacent to each other in solar cell array 110.

In modification example 2, solar cell 10X and solar cell 101 have a similar configuration as shown in FIG. 16. On the other hand, the direction of solar cell 10X is different from that of solar cell 10Y by 180°.

Here, second rear surface electrode 12B of solar cell 10X and second light-receiving surface electrode 13B of solar cell 10Y are preferably arranged on an approximately straight line. Similarly, second light-receiving surface electrode 13B of solar cell 10X and second rear surface electrode 12B of solar cell 101 are preferably arranged on an approximately straight line.

### (Configuration of Wiring Substrate)

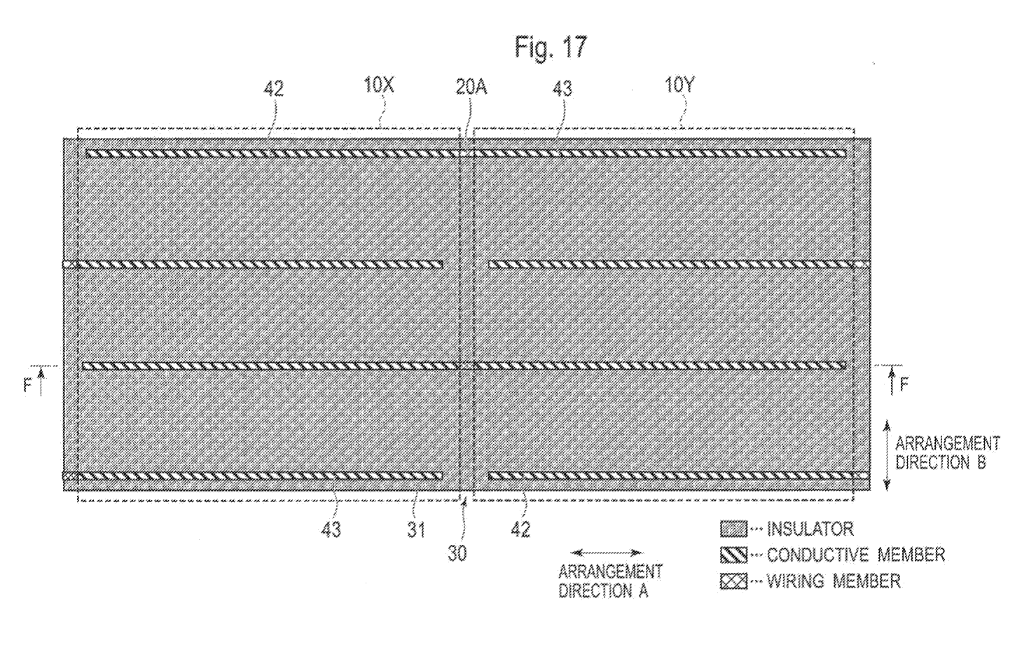

In the following, the configuration of the wiring substrate according to modification example 2 is described with reference to the drawings. FIG. 17 is a view showing wiring substrate 30 according to modification example 2.

Here, the case is illustrated where wiring substrate 30 covers rear surface 11N of solar cell 10X and rear surface 11N of solar cell 10Y. FIG. 17 is a view showing one of the faces of wiring substrate 30, which is opposed to rear surface 11N.

As shown in FIG. 17, conductive member 42, conductive member 43, and wiring member 20A are provided across multiple solar cells 10. In the second embodiment, conductive member 42, conductive member 43, and wiring member 20A are provided across multiple solar cells 10 on an approximately straight line.

Modification example 2 is similar to the first embodiment in that conductive member 42 is provided in groove 32 of wiring substrate 30, and conductive member 43 is provided in groove 33 of wiring substrate 30. Similarly, modification example 2 is similar to the first embodiment in that wiring member 20A is provided in groove 34 of wiring substrate 30. That is, the grooves of wiring substrate 30 (groove 32, groove 33, and groove 34) are provided across multiple solar cells 10 on an approximately straight line.

### (Connection Between Solar Cells)

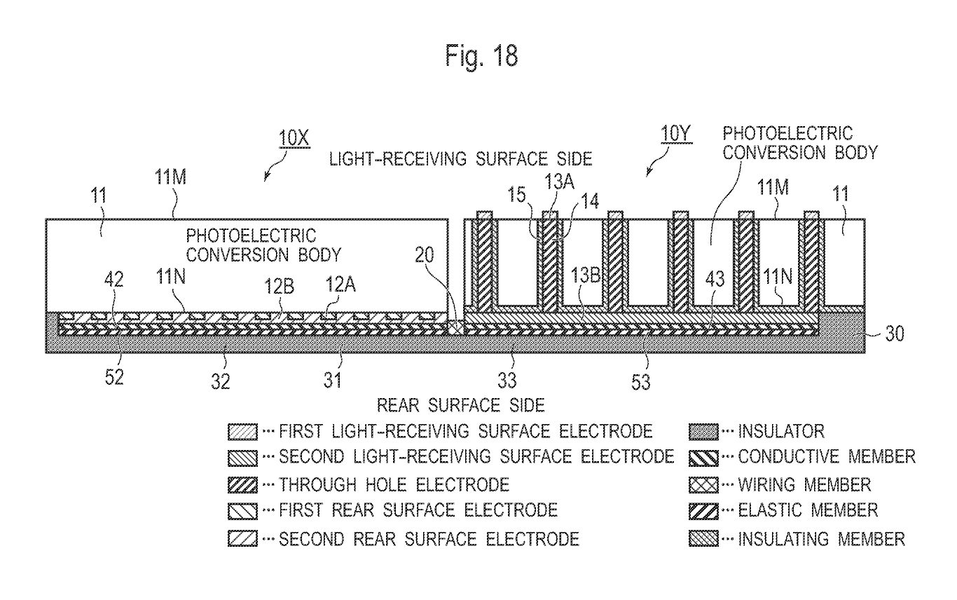

In the following, the connection between the solar cells according to modification example 2 is described with reference to the drawings. FIG. 18 is a view showing the cross sections of solar cell 10 and wiring substrate 30 according to modification example 2. Specifically, FIG. 18 is a view showing the cross sections (taken along the line F-F shown in FIG. 17) of solar cell 10 and wiring substrate 30.

As shown in FIG. 18, second rear surface electrode 12B of solar cell 10X is electrically connected to wiring member 20A via conductive member 42. On the other hand, second light-receiving surface electrode 13B of solar cell 10Y is electrically connected to wiring member 20A via conductive member 43. Thus, second rear surface electrode 12B of solar cell 10X and second light-receiving surface electrode 13B of solar cell 10Y are electrically connected to each other by wiring member 20A.

Also, as shown in FIG. 18, elastic member 52 is provided between the bottom of groove 32 and conductive member 42. Also, elastic member 53 is provided between the bottom of groove 33 and conductive member 43. For elastic member 52 and elastic member 53, a rubber resin, a silicone resin, a urethane resin, an epoxy resin, a resin having a porous structure, and the like may be used.

### (Operations and Effects)

In modification example 2, second rear surface electrode 12B of solar cell 10X and second light-receiving surface electrode 13B of solar cell 10Y are arranged on an approximately straight line. Similarly, second light-receiving surface electrode 13B of solar cell 10X and second rear surface electrode 12B of solar cell 10Y are arranged on an approximately straight line.

Thus, the grooves of wiring substrate 30 (groove 32, groove 33, and groove 34) are provided across multiple solar cells 10 on an approximately straight line. That is, the pattern of the grooves of wiring substrate 30 is simple.

In modification example 2, elastic member 52 is provided between the bottom of groove 32 and conductive member 42, and elastic member 53 is provided between the bottom of groove 33 and conductive member 43. Consequently, the stress generated when wiring substrate 30 is bonded to photoelectric conversion body 11 is relieved by elastic member 52 and elastic member 53.

### Second Embodiment

In the following, the second embodiment is described with reference to the drawings. In the following, points of the second embodiment different from those of the first embodiment are mainly described.

Specifically, in the first embodiment, an electrode is provided to both of light-receiving surface 11M and rear surface 11N. On the contrary, in the second embodiment, the electrodes are grouped together on rear surface 11N.

### (Arrangement of Solar Cells)

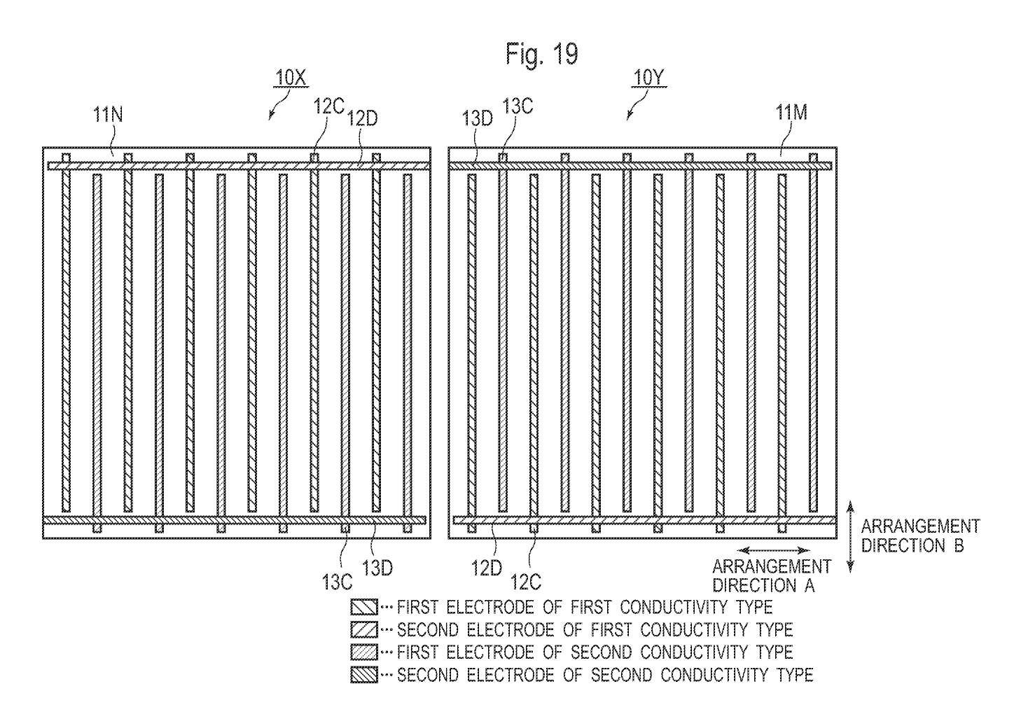

In the following, an arrangement of solar cells according to the second embodiment is described with reference to the drawings. FIG. 19 is a view showing an arrangement of solar cells 10 according to the second embodiment. Note that FIG. 19 is a view of solar cells 10 viewed from the rear surface side.

Here, solar cell 10X and solar cell 10Y out of multiple solar cells 10 are described as an example. Solar cell 10X and solar cell 10Y are solar cells 10 adjacent to each other in solar cell array 110.

In the second embodiment, solar cell 10 has first electrode 12C of a first conductivity type and second electrode 12D of a first conductivity type instead of first rear surface electrode 12A and second rear surface electrode 12B. Similarly, solar cell 10 has first electrode 13C of a second conductivity type and second electrode 13D of a second conductivity type instead of first light-receiving surface electrode 13A and second light-receiving surface electrode 13B.

First electrode 12C of the first conductivity type and second electrode 12D of the first conductivity type form first electrode 12 that collects carriers (positive holes or electrons). First electrode 12C of the first conductivity type and second electrode 12D of the first conductivity type are provided on rear surface 11N of photoelectric conversion body 11, and are made of, for example, low resistance metal such as Ag and Cu.

Specifically, first electrode 12C of the first conductivity type has a linear shape extending in arrangement direction B. Second electrode 12D of the first conductivity type has a linear shape extending in arrangement direction A. Second electrode 12D of the first conductivity type is provided at an end of solar cell 10 in arrangement direction B.

Multiple first electrodes 12C of the first conductivity type are preferably provided substantially across the entire area of rear surface 11N of photoelectric conversion body 11. Second electrode 12D of the first conductivity type intersects with and is electrically connected to multiple first electrodes 12C of the first conductivity type on rear surface 11N of photoelectric conversion body 11.

First electrode 13C of the second conductivity type and second electrode 13D of the second conductivity type form second electrode 13 that collects carriers (electrons or positive holes). First electrode 13C of the second conductivity type and second electrode 13D of the second conductivity type are provided on rear surface 11N of photoelectric conversion body 11, and are made of, for example, low resistance metal such as Ag and Cu.

Specifically, first electrode 13C of the second conductivity type has a linear shape extending in arrangement direction B. Second electrode 13D of the second conductivity type has a linear shape extending in arrangement direction A. Second electrode 13D of the second conductivity type is provided at an end of solar cell 10 in arrangement direction B.

Multiple first electrodes 13C of the second conductivity type are preferably provided substantially across the entire area of rear surface 11N of photoelectric conversion body 11. Second electrode 13D of the second conductivity type intersects with and is electrically connected to multiple first electrodes 13C of the second conductivity type on rear surface 11N of photoelectric conversion body 11.

Here, it should be noted that first electrode 12C of the first conductivity type and second electrode 12D of the first conductivity type are provided so as not to be electrically connected to first electrode 13C of the second conductivity type and second electrode 13D of the second conductivity type.

In the second embodiment, the first conductivity type region and the second conductivity type region are each partially formed in rear surface 11N of photoelectric conversion body 11. First electrode 12C of the first conductivity type and second electrode 12D of the first conductivity type are formed in the first conductivity type region partially formed in rear surface 11N of photoelectric conversion body 11. First electrode 13C of the second conductivity type and second electrode 13D of the second conductivity type are formed in the second conductivity type region partially formed in rear surface 11N of photoelectric conversion body 11.

In the second embodiment, solar cell 10X and solar cell 10Y have a similar configuration as shown in FIG. 19. On the other hand, the direction of solar cell 10X is different from that of solar cell 10Y by 180°.

Here, second electrode 12D of the first conductivity type of solar cell 10X and second electrode 13D of the second conductivity type of solar cell 10Y are arranged on an approximately straight line. Similarly, second electrode 13D of the second conductivity type of solar cell 10X and second electrode 12D of the first conductivity type of solar cell 10Y are arranged on an approximately straight line.

### (Configuration of Wiring Substrate)

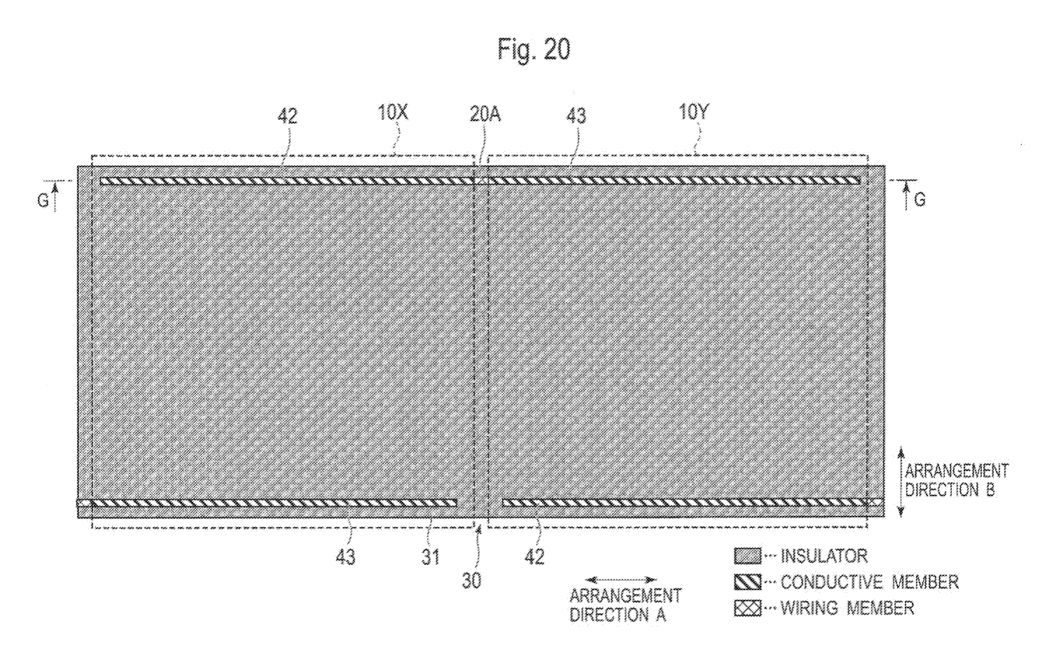

In the following, the configuration of the wiring substrate according to the second embodiment is described with reference to the drawing. FIG. 20 is a view showing wiring substrate 30 according to the second embodiment.

Here, the case is illustrated where wiring substrate 30 covers rear surface 11N of solar cell 10X and rear surface 11N of solar cell 10Y. FIG. 20 is a view showing one of the faces of wiring substrate 30, which is opposed to rear surface 11N.

As shown in FIG. 20, conductive member 42, conductive member 43, and wiring member 20A are provided across multiple solar cells 10 on an approximately straight line.

The second embodiment is similar to the first embodiment in that conductive member 42 is provided in groove 32 of wiring substrate 30, and conductive member 43 is provided in groove 33 of wiring substrate 30. Similarly, the second embodiment is similar to the first embodiment in that wiring member 20A is provided in groove 34 of wiring substrate 30. That is, the grooves of wiring substrate 30 (groove 32, groove 33, and groove 34) are provided across multiple solar cells 10 on an approximately straight line.

Also, in the second embodiment, groove 32 is provided along second electrode 12D of the first conductivity type instead of second rear surface electrode 12B. Similarly, groove 33 is provided along second electrode 13D of the second conductivity type instead of second light-receiving surface electrode 13B.

### (Connection Between Solar Cells)

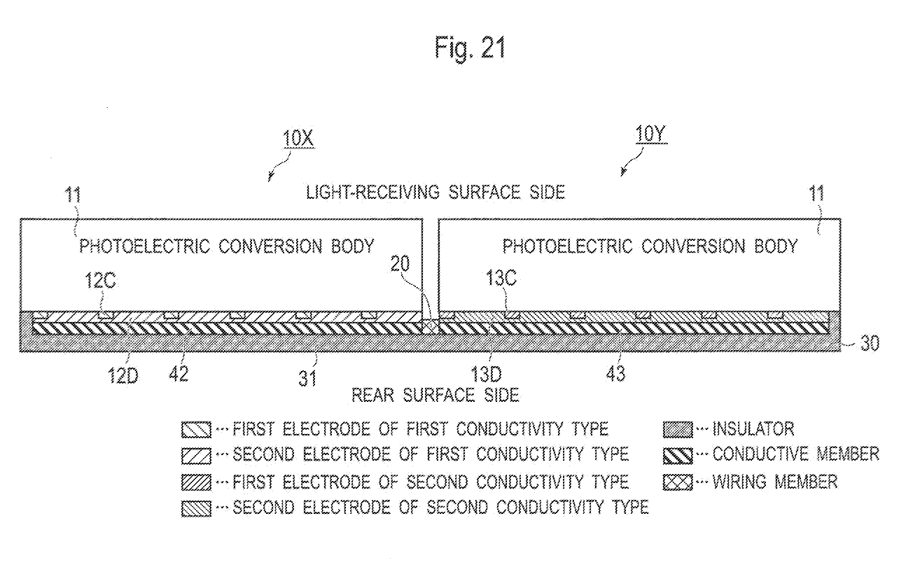

In the following, the connection between the solar cells according to the second embodiment is described with reference to the drawing. FIG. 21 is a view showing the cross sections of solar cell 10 and wiring substrate 30 according to the second embodiment. Specifically, FIG. 21 is a view showing the cross sections (taken along the line G-G shown in FIG. 20) of solar cell 10 and wiring substrate 30.

As shown in FIG. 21, second electrode 12D of the first conductivity type of solar cell 10X is electrically connected to wiring member 20A via conductive member 42. On the other hand, second electrode 13D of the second conductivity type of solar cell 10Y is electrically connected to wiring member 20A via conductive member 43. Thus, second electrode 12D of the first conductivity type of solar cell 10X and second electrode 13D of the second conductivity type of solar cell 10Y are electrically connected to each other by wiring member 20A.

### (Operations and Effects)

According to the second embodiment, in solar cell module 100 in which the electrodes are grouped together on the rear surface side, effects similar to those in the first embodiment can be obtained.

### Modification Example 1

In the following, modification example 1 of the second embodiment is described with reference to the drawing. In the following, points of modification example 1 different from those of the second embodiment are mainly described.

Specifically, in modification example 1, the pattern of the electrodes is different from that of the second embodiment. In modification example 1, an elastic member is provided between the bottom of the grooves (groove 32 and groove 33), and the conductive member (conductive member 42 and conductive member 43).

### (Arrangement of Solar Cells)

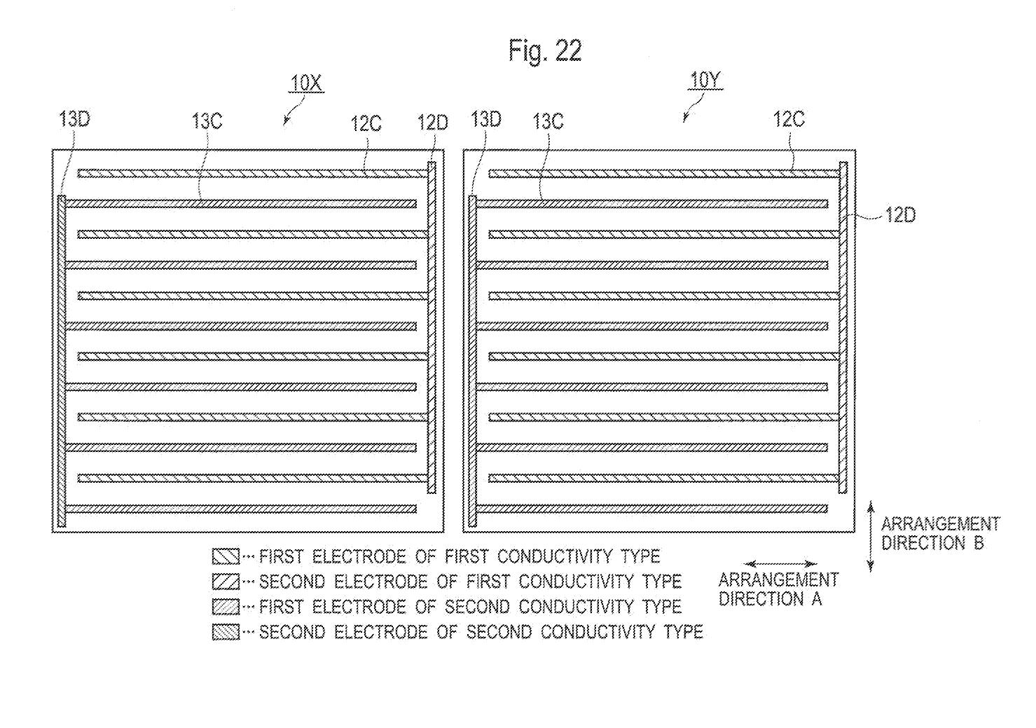

In the following, the arrangement of the solar cells according to modification example 1 is described with reference to the drawing. FIG. 22 is a view showing the arrangement of solar cells 10 according to modification example 1. FIG. 22 is a view of solar cells 10 viewed from the rear surface side.

Here, solar cell 10X and solar cell 10Y out of multiple solar cells 10 are described as an example. Solar cell 10X and solar cell 10Y are solar cells 10 adjacent to each other in solar cell array 110.

In modification example 1, solar cell 10X and solar cell 10Y have a similar configuration as shown in FIG. 22. Also, the direction of solar cell 10X is the same as that of solar cell 10Y.

Here, first electrode 12C of the first conductivity type has a linear shape extending in arrangement direction A. Second electrode 12D of the first conductivity type has a linear shape extending in arrangement direction B. Second electrode 12D of the first conductivity type is provided at an end of solar cell 10 in arrangement direction A.

Also, first electrode 13C of the second conductivity type has a linear shape extending in arrangement direction A. second electrode 13D of the second conductivity type has a linear shape extending in arrangement direction D. Second electrode 13D of the second conductivity type is provided at an end of solar cell 10 in arrangement direction A.

Second electrode 13D of the second conductivity type is provided at an end of solar cell 10 in arrangement direction A.

In modification example 1, second rear surface electrode 12B of solar cell 10X and second light-receiving surface electrode 13B of solar cell 10Y are provided in arrangement direction B at the boundary between solar cell 10X and solar cell 10Y.

### (Configuration of Wiring Substrate)

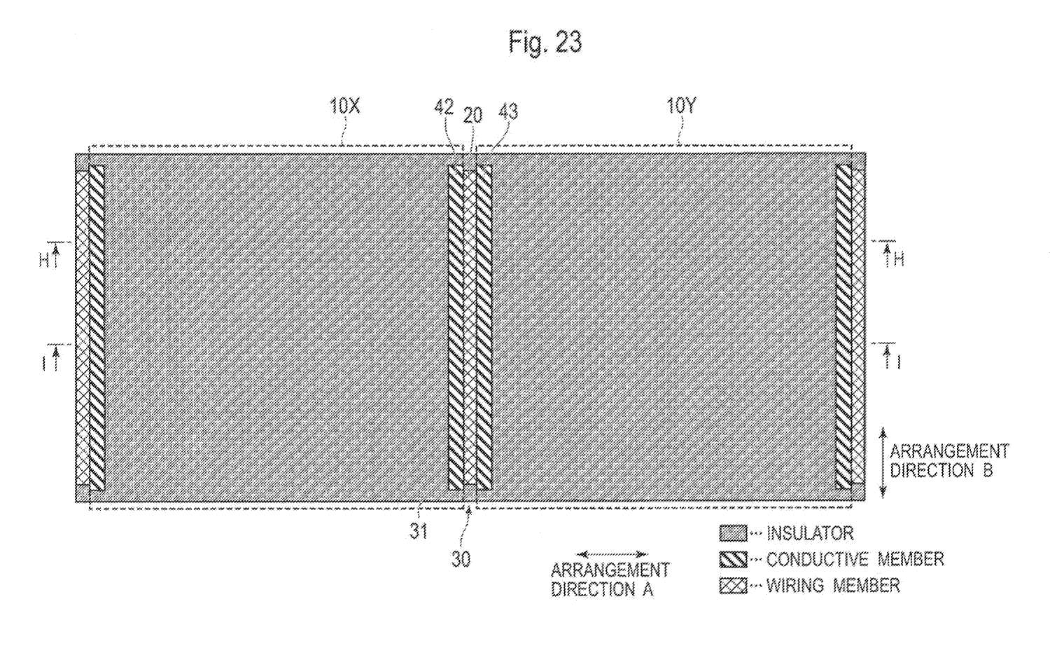

In the following, the configuration of the wiring substrate according to modification example 1 is described with reference to the drawing. FIG. 23 is a view showing wiring substrate 30 according to modification example 1.

Here, the case is illustrated where wiring substrate 30 covers rear surface 11N of solar cell 10X and rear surface 11N of solar cell 10Y. FIG. 23 is a view showing one of the faces of wiring substrate 30, which is opposed to rear surface 11N.

As shown in FIG. 23, conductive member 42, conductive member 43, and wiring member 20A have a shape extending in arrangement direction B at the boundary between solar cell 10X and solar cell 10Y.

Modification example 1 is similar to the first embodiment in that conductive member 42 is provided in groove 32 of wiring substrate 30, and conductive member 43 is provided in groove 33 of wiring substrate 30. Similarly, modification example 1 is similar to the first embodiment in that wiring member 20A is provided in groove 34 of wiring substrate 30. That is, the grooves of wiring substrate 30 (groove 32, groove 33, and groove 34) have a shape extending in arrangement direction B at the boundary between solar cell 10X and solar cell 10Y.

### (Connection Between Solar Cells)

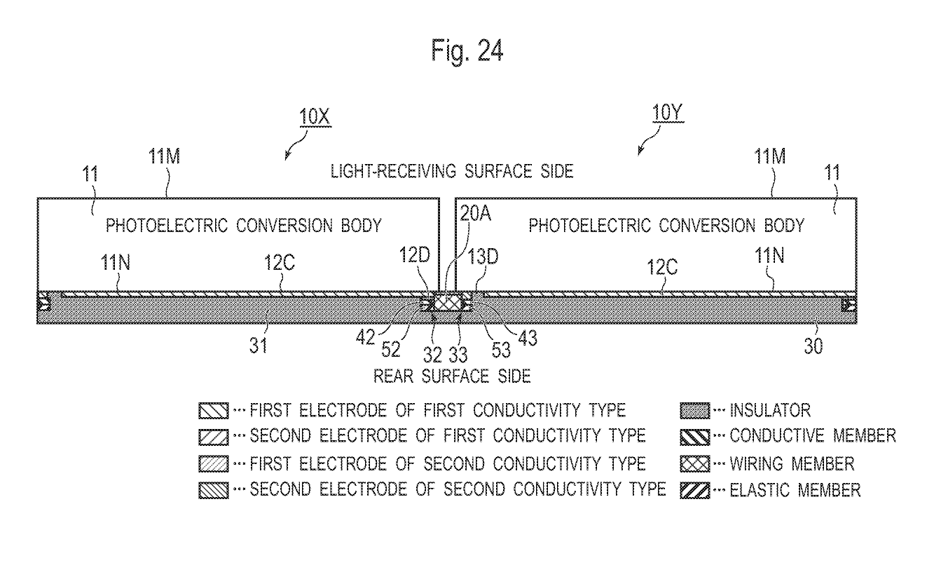

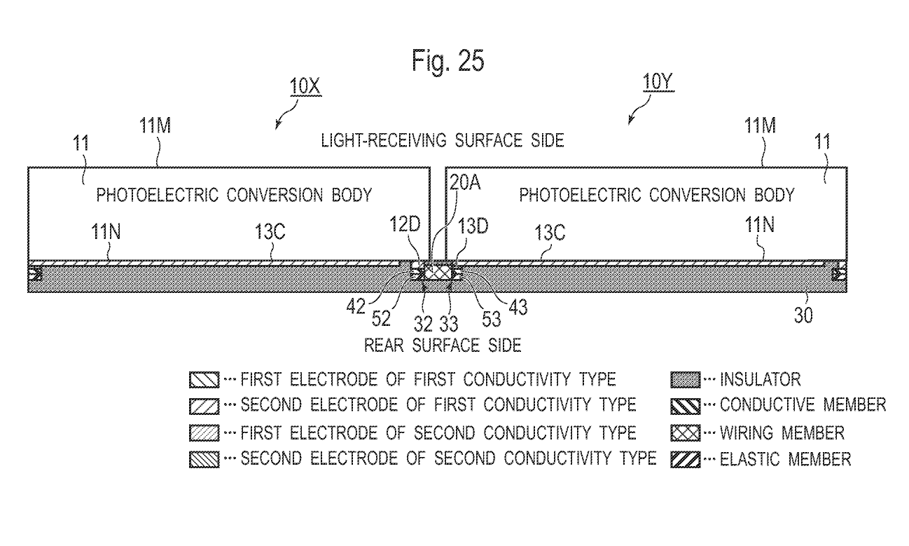

In the following, the connection between the solar cells according to modification example 1 is described with reference to the drawings. FIGS. 24 and 25 are views showing the cross sections of solar cell 10 and wiring substrate 30 according to modification example 1. Specifically, FIG. 24 is a view showing the cross sections (taken along the line H-H shown in FIG. 23) of solar cell 10 and wiring substrate 30. FIG. 25 is a view showing the cross sections (taken along the line I-I shown in FIG. 23) of solar cell 10 and wiring substrate 30.

As shown in FIG. 24, second electrode 12D of the first conductivity type of solar cell 10X is electrically connected to wiring member 20A via conductive member 42. On the other hand, second electrode 12D of the first conductivity type of solar cell 10X is insulated from second electrode 12D of the first conductivity type of solar cell 10Y by wiring substrate 30 (insulator 31).

As shown in FIG. 25, second electrode 13D of the second conductivity type of solar cell 10Y is electrically connected to wiring member 20A via conductive member 43. On the other hand, second electrode 13D of the second conductivity type of solar cell 10Y is insulated from second electrode 13D of the second conductivity type of solar cell 10X by wiring substrate 30 (insulator 31).

As shown in FIG. 25, second electrode 13D of the second conductivity type of solar cell 10Y is insulated from conductive member 3D.

In this manner, second electrode 12D of the first conductivity type of solar cell 10X and second electrode 13D of the second conductivity type of solar cell 10Y are electrically connected to each other by wiring member 20A.

Also, elastic member 52 is provided between the bottom of groove 32 and conductive member 42 as shown in FIGS. 24 and 25. Also, elastic member 53 is provided between the bottom of groove 33 and conductive member 43. For elastic member 52 and elastic member 53, a rubber resin, a silicone resin, a urethane resin, an epoxy resin, a resin having a porous structure, and the like may be used.

### (Operations and Effects)

In modification example 1, second rear surface electrode 12B of solar cell 10X and second light-receiving surface electrode 13B of solar cell 10Y are provided in arrangement direction B at the boundary between solar cell 10X and solar cell 10Y.

Thus, the grooves of wiring substrate 30 (groove 32, groove 33, and groove 34) are grouped together into one groove at the boundary of multiple solar cells 10. That is, the pattern of the grooves of wiring substrate 30 is simple.

In modification example 1, elastic member 52 is provided between the bottom of groove 32 and conductive member 42, and elastic member 53 is provided between the bottom of groove 33 and conductive member 43. Consequently, the stress generated when wiring substrate 30 is bonded to photoelectric conversion body 11 is relieved by elastic member 52 and elastic member 53.

### Third Embodiment

In the following, the third embodiment is described with reference to the drawings. In the following, points of the third embodiment different from those of the first embodiment are mainly described.

Specifically, in the first embodiment, first light-receiving surface electrode 13A is provided on light-receiving surface 11M of photoelectric conversion body 11. Second light-receiving surface electrode 13B is provided on rear surface 11N of photoelectric conversion body 11. On the contrary, in the third embodiment, both of first light-receiving surface electrode 13A and second light-receiving surface electrode 13B are provided on light-receiving surface 11M of photoelectric conversion body 11.

### (Configuration of Solar Cell Module)

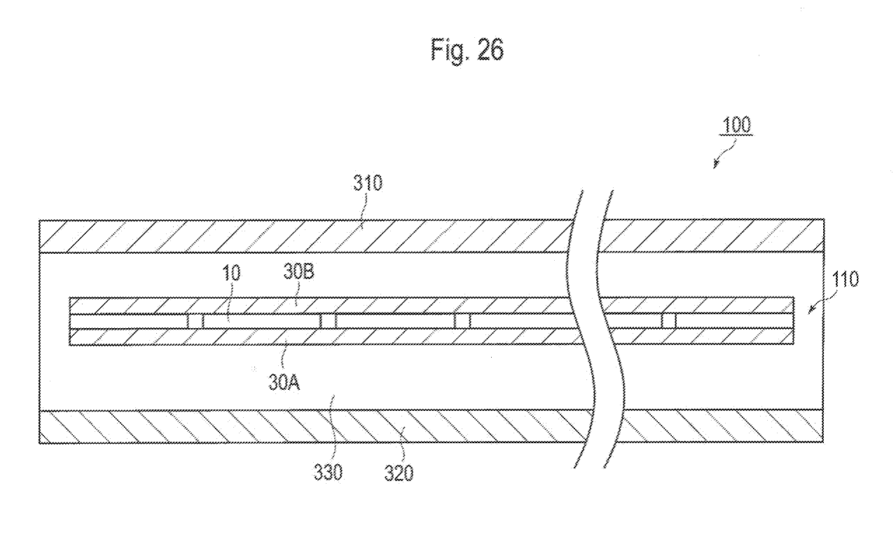

In the following, the configuration of a solar cell module according to the third embodiment is described with reference to the drawings. FIG. 26 is a view showing the configuration of solar cell module 100 according to the third embodiment. Note that FIG. 26 is a view showing a cross section of solar cell module 100.

As shown in FIG. 26, solar cell module 100 has light-receiving surface member 310, rear surface member 320, and sealing material 330. The configuration of light-receiving surface member 310, rear surface member 320, and sealing material 330 is similar to that of the first embodiment.

In the third embodiment, wiring substrate 30A is provided at the rear surface side of multiple solar cells 10. Moreover, wiring substrate 30B is provided at the light-receiving surface side of multiple solar cells 10.

### (Configuration of Solar Cell)

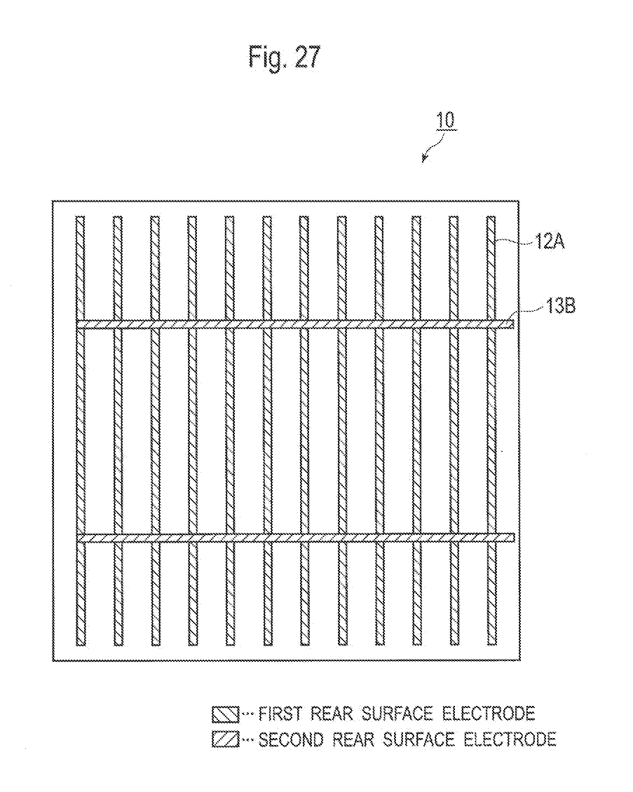

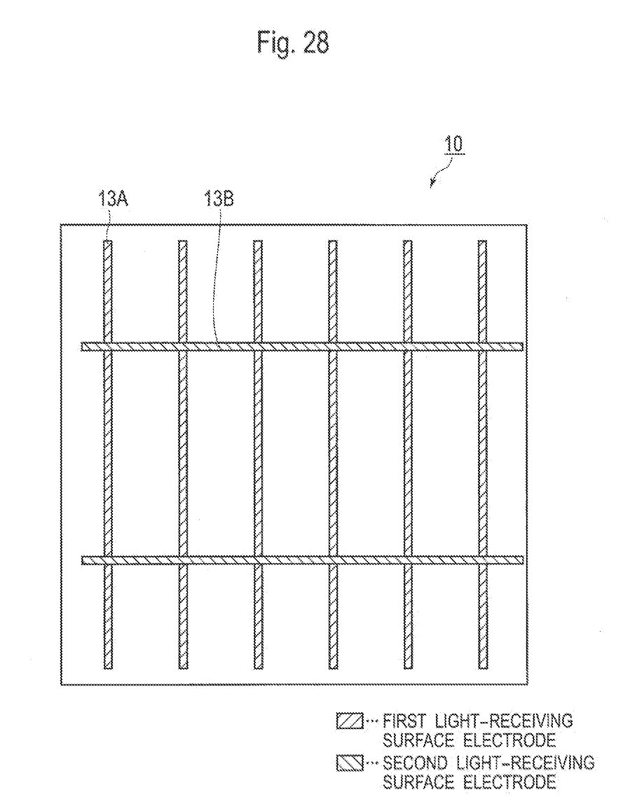

In the following, the configuration of the solar cell according to the third embodiment is described with reference to the drawings. FIGS. 27 and 28 are views showing the configuration of solar cell 10 according to the third embodiment. Note that FIG. 27 is a view of solar cell 10 viewed from the rear surface that is provided on the opposite side to the light-receiving surface which receives irradiated light. FIG. 28 is a view of solar cell 10 viewed from the light-receiving surface that receives irradiated light.

As shown in FIG. 27, first rear surface electrode 12A and second rear surface electrode 12B are provided on rear surface 11N of photoelectric conversion body 11. Multiple first rear surface electrodes 12A are provided with a predetermined space therebetween. Second rear surface electrode 12B intersects with multiple first rear surface electrodes 12A in rear surface 11N of photoelectric conversion body 11.

As shown in FIG. 28, first light-receiving surface electrode 13A and second light-receiving surface electrode 13B are provided on rear surface 11M of photoelectric conversion body 11. Multiple first light-receiving surface electrodes 13A are provided with a predetermined space therebetween. Second light-receiving surface electrode 13B intersects with multiple first light-receiving surface electrodes 13A in light-receiving surface 11M of photoelectric conversion body 11.

In the third embodiment, similarly to the first embodiment, the first conductivity type region is formed in light-receiving surface 11M of photoelectric conversion body 11, and the second conductivity type region is formed in rear surface 11N of photoelectric conversion body 11.

### (Connection Between Solar Cells)

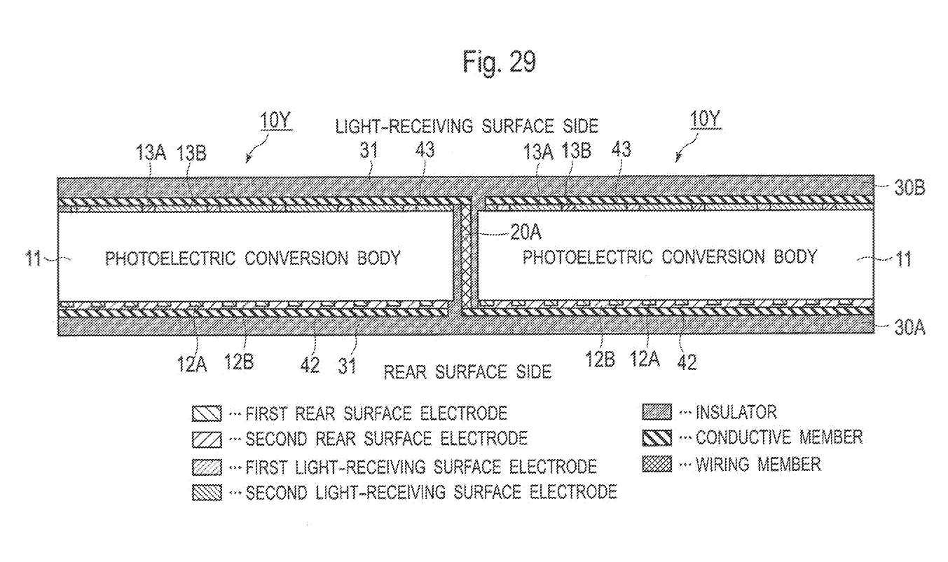

In the following, the connection between the solar cells according to the third embodiment is described with reference to the drawing. FIG. 29 is a view showing the cross sections of solar cell 10, wiring substrate 30A, and wiring substrate 30B according to the third embodiment. Here, the case is illustrated where wiring substrate 30A and wiring substrate 30B cover rear surface 11N of solar cell 10X and rear surface 11N of solar cell 10Y.

As shown in FIG. 29, second light-receiving surface electrode 13B of solar cell 10X is electrically connected to wiring member 20A via conductive member 43. On the other hand, second rear surface electrode 12B of solar cell 10Y is electrically connected to wiring member 20A via conductive member 42. Consequently, second light-receiving surface electrode 13B of solar cell 10X and second rear surface electrode 12B of solar cell 10Y are electrically connected to each other by wiring member 20A.

Here, in the third embodiment, wiring substrate 30A is provided with groove 32, and wiring substrate 30B is provided with groove 33. The third embodiment is similar to the first embodiment in that groove 32 is provided along second rear surface electrode 12B, and groove 33 is provided along second light-receiving surface electrode 13B. Also, the third embodiment is similar to the first embodiment in that groove 32 is provided with conductive member 42, and groove 33 is provided with conductive member 43.

### Other Embodiments

In each embodiment, the case has been illustrated where wiring substrate 30 covers the main surfaces the light-receiving surface or the rear surface) of two solar cells 10. However, the invention is not limited to this case. Specifically, wiring substrate 30 may cover the main surfaces (the light-receiving surface or the rear surface) of three or more solar cells 10. Also, wiring substrate 30 may cover two or more solar cells 10 both within solar cell array 110 and between solar cell strings 110.

Although not specifically mentioned in the embodiments, the entire region in which wiring substrate 30 is disposed is preferably at the inner side of the entire region in which solar cells 10 are disposed. Thereby, an increase of the size of solar cell module 100 can be suppressed.

As a matter of course, the elastic members shown in modification example 1 of the first embodiment and in modification example 2 of the second embodiment (elastic member 52 and elastic member 53) can be applied to other embodiments or modification examples.

As shown in the first embodiment, wiring substrate 30 across solar cell arrays 110 can be applied to other embodiments or modification examples, as a matter of course.

The above-described related technology has no specific reference for alignment of the wiring substrate with the solar cell, thus the above-mentioned alignment is difficult. Especially, in the case where a wiring substrate is provided across multiple solar cells in a solar cell module, the alignment of the wiring substrate with the multiple solar cells is more difficult.

According to the embodiments above, solar cell modules that enable easy alignment of wiring substrate with solar cells is provided, and also simplified manufacturing process.

The invention includes other embodiments in addition to the above-described embodiments without departing from the spirit of the invention. The embodiments are to be considered in all respects as illustrative, and not restrictive. The scope of the invention is indicated by the appended claims rather than by the foregoing description. Hence, all configurations including the meaning and range within equivalent arrangements of the claims are intended to be embraced in the invention.

What is claimed is:

1. A solar cell module comprising:
a plurality of solar cells each comprising:
a photoelectric conversion body that generates carriers upon exposure to light; and
an electrode provided on a main surface of the photoelectric conversion body, which collects the carriers from the photoelectric conversion body;
a wiring member that electrically connects the plurality of solar cells; and
a wiring substrate that covers the main surfaces of at least two or more solar cells out of the plurality of solar cells, the wiring substrate comprising a groove provided along at least a part of the electrodes, wherein
a conductive member is provided at the bottom of the groove, and
the conductive member electrically connects the electrodes to the wiring member.

2. The solar cell module of claim 1, further comprising a linear solar cell array comprised of a group of solar cells electrically connected to each other by the wiring member in a predetermined arrangement direction, wherein
the width of the wiring substrate is smaller than the width of the solar cell string.

3. The solar cell module of claim 1, wherein
the wiring member is provided inside the groove.

4. The solar cell module of claim 1, wherein
the groove is provided to extend continuously across at least two or more solar cells, and the wiring member is provided inside the groove.

5. The solar cell module of claim 1, wherein
the wiring member electrically connects at least two or more solar cells to each other.

6. The solar cell module of claim 1, further comprising an elastic member provided between the bottom of the groove and the conductive member.

7. The solar cell module of claim 1, further comprising a plurality of solar cell arrays, each comprised of a group of solar cells electrically connected to each other by the wiring member in a predetermined arrangement direction, wherein
the plurality of solar cell arrays include a first solar cell array and a second solar cell array adjacent to the first solar cell array;
a first solar cell provided at one end of the first solar cell array is electrically connected to a second solar cell provided at one end of the second solar cell array by the wiring member; and
the wiring substrate covers the main surface of the first solar cell and the main surface of the second solar cell.
